(19) United States
(12) Patent Application Publication
(10) Pub. No.: US 2026/0205061 A1
(43) Pub. Date: Jul. 16, 2026

(54) CURRENT-CONTROLLED OSCILLATOR-BASED RIPPLE REDUCTION LOOP FOR BANDGAP REFERENCE

(71) Applicant: KOREA ADVANCED INSTITUTE OF SCIENCE AND TECHNOLOGY, Daejeon (KR)

(72) Inventors: Seonghwan CHO, Daejeon (KR); Pangi PARK, Daejeon (KR)

(73) Assignee: KOREA ADVANCED INSTITUTE OF SCIENCE AND TECHNOLOGY, Daejeon (KR)

(21) Appl. No.: 19/441,011

(22) Filed: Jan. 6, 2026

(30) Foreign Application Priority Data
Jan. 16, 2025 (KR) 10-2025-0006733

(51) Int. Cl. H03F 1/30; H03M 1/06

(52) U.S. Cl. CPC H03F 1/301; H03M 1/0607; H03F 2200/375

(57) ABSTRACT

A loop circuit for a bandgap reference circuit includes: an oscillator configured to oscillate based on a gate voltage of the bandgap reference circuit; an offset detector configured to detect an offset voltage generated in an amplifier of the bandgap reference circuit by counting an oscillation frequency output from the oscillator; and a converter configured to adjust an input voltage of the amplifier based on a control signal output from the offset detector.

### CROSS REFERENCE TO RELATED APPLICATIONS

This application claims the benefit of and priority to Korean Patent Applications No. 10-2025-0006733, filed on Jan. 16, 2025, which is incorporated by reference herein in its entirety.

### BACKGROUND OF THE DISCLOSURE

### (1) Field of the Disclosure

The present disclosure relates to a ripple reduction loop, and more particularly, to a current-controlled oscillator-based loop circuit for reducing ripple in a bandgap reference circuit.

### (2) Description of Related Art

A bandgap reference circuit is an essential circuit used in analog-to-digital converters (ADCs), power regulators, and the like for generating a voltage that remains substantially independent of temperature variations. The bandgap reference circuit generates, within the circuit, a voltage proportional to temperature and a voltage inversely proportional to temperature, and then multiplies each by a predetermined constant and sums them so that the temperature-dependent variation of the resulting sum is minimized. In this case, the temperature dependence is degraded due to an offset generated in an amplifier within the bandgap reference circuit, and a chopping technique is employed to eliminate the offset. As a result, the influence of the offset is eliminated; however, a problem arises in that ripple is generated in the output voltage (reference voltage) due to the up-modulated offset. If a bandgap reference circuit in which ripple is generated is used in an ADC and a power regulator, the resolution of the ADC is limited, and in the case of the power regulator, the ripple manifests as noise in the output power.

To address this problem, conventionally, a notch filter configured to perform band-stop filtering on the ripple component present at the chopping frequency has been attached to the output of the amplifier. A notch filter may be simply implemented using a switched capacitor; however, in order to remove ripple, a large capacitor of several picofarads (pF) or more is required for the notch filter, which increases the cost per unit area and thus gives rise to a problem of excessively high cost in modern advanced manufacturing processes. Additionally, when a notch filter is used to remove ripple in a bandgap reference circuit, a problem also arises in that a residual offset is generated due to a mismatch between the two paths of the notch filter.

### SUMMARY

The present disclosure is directed to a loop circuit capable of effectively removing ripple of a bandgap reference circuit at low cost.

Furthermore, the present disclosure is directed to a loop circuit for removing the ripple of a bandgap reference circuit based on a current-controlled oscillator.

According to an embodiment of the present disclosure, a loop circuit for a bandgap reference circuit includes: an oscillator configured to oscillate based on a gate voltage of the bandgap reference circuit; an offset detector configured to detect an offset voltage generated in an amplifier of the bandgap reference circuit by counting an oscillation frequency output from the oscillator; and a converter configured to adjust an input voltage of the amplifier based on a control signal output from the offset detector.

In some embodiments, the converter may be provided in the amplifier and may include a plurality of transistors.

In some embodiments, the plurality of transistors may include at least one MOSFET (Metal-Oxide-Semiconductor Field-Effect-Transistor).

In some embodiments, the offset detector may include: a counter configured to count the oscillation frequency based on a chopping frequency of the bandgap reference circuit; a sign detector configured to detect a sign of the offset voltage based on the chopping frequency and an output value of the counter; and an integrator configured to output the control signal based on the detected sign.

In some embodiments, the counter may, for each chopping cycle of the chopping frequency, up-count the oscillation frequency from a rising edge and down-count the oscillation frequency from a falling edge, and may output a counted value resulting therefrom.

In some embodiments, the sign detector may compare the counted value with a reference value for each chopping cycle and may output a bit value indicating the sign of the offset voltage.

In some embodiments, the integrator may increase or decrease a control value using the bit value for each chopping cycle and may output a control signal corresponding to the control value.

According to another embodiment of the present disclosure, a method for reducing ripple in a bandgap reference circuit, performed by a loop circuit provided in the bandgap reference circuit, may include: generating an oscillation frequency based on a gate voltage of the bandgap reference circuit; detecting an offset voltage generated in an amplifier of the bandgap reference circuit by counting the oscillation frequency; and adjusting a voltage input to the amplifier based on the detected offset voltage.

### BRIEF DESCRIPTION OF THE DRAWINGS

FIG. 1 is a circuit diagram schematically illustrating a ripple reduction loop circuit according to an embodiment of the present disclosure.

FIG. 2 is a view for explaining an offset detection process according to an embodiment of the present disclosure.

FIG. 3 is a view illustrating an oscillation frequency used by a ripple reduction loop circuit according to an embodiment of the present disclosure.

FIG. 4 is a view illustrating an operation of a counter in a ripple reduction loop circuit according to an embodiment of the present disclosure.

FIG. 5 is a view illustrating a process in which a ripple reduction loop circuit according to an embodiment of the present disclosure generates a control signal.

FIG. 6 is an exemplary view illustrating an oscillator applied to a ripple reduction loop circuit according to an embodiment of the present disclosure.

FIG. 7 is an exemplary view illustrating a unit element within a converter of a ripple reduction loop circuit according to an embodiment of the present disclosure.

FIG. 8 is a flowchart illustrating a ripple reduction method according to an embodiment of the present disclosure.

FIG. 9 is a view illustrating an output of a bandgap reference circuit with a ripple reduction loop turned off according to an embodiment of the present disclosure.

FIG. 10 is a diagram illustrating an output of a bandgap reference circuit with the ripple reduction loop turned on according to an embodiment of the present disclosure.

### DETAILED DESCRIPTION OF THE DISCLOSURE

The advantages and features of the present disclosure, and methods for achieving the same, will become apparent from the following detailed description of embodiments taken in conjunction with the accompanying drawings. However, the present disclosure is not limited to the embodiments disclosed below, but may be embodied in various different forms. The embodiments are provided merely to make the disclosure of the present disclosure complete and to fully inform those of ordinary skill in the art of the scope of the disclosure. The present disclosure is defined only by the scope of the appended claims. Therefore, in some embodiments, well-known process steps, well-known device structures, and well-known technologies are not described in detail so as to avoid obscuring the present disclosure.

The terms used herein have been selected from among generally accepted terms that are currently widely used, while taking into account their functions in the present disclosure. However, these terms may be interpreted differently depending on the intent of those skilled in the art, legal precedent, or the emergence of new technologies. In addition, in certain cases, there are terms arbitrarily selected by the applicant, and in such cases, the meanings of the terms will be described in detail in the corresponding description of the disclosure. Therefore, the terms used in this specification should be interpreted based on their meanings and the overall content of the present disclosure, rather than as mere names of the terms.

Throughout this specification, when it is stated that a part “includes” a component, this means that it may include other components, not that it excludes them, unless otherwise stated.

In addition, although terms such as “first,” “second,” and “third” may be used herein to describe various components, these components should not be limited by said terms. The above terms are used for the purpose of distinguishing one component from another.

Hereinafter, embodiments of the present disclosure will be described in detail with reference to the accompanying drawings so that those of ordinary skill in the art to which the present disclosure pertains may readily implement the disclosure. In the drawings, parts that are not relevant to the description are omitted to clearly explain the present disclosure. Throughout this specification, the same reference numerals denote the same elements.

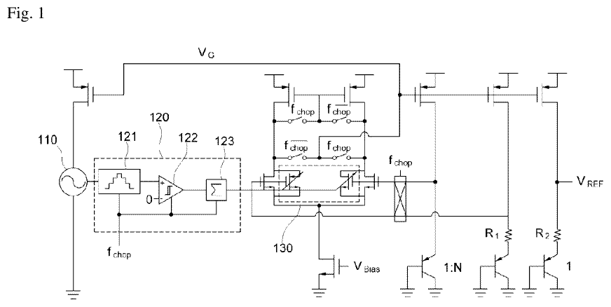

FIG. 1 is a circuit diagram schematically illustrating a ripple reduction loop circuit according to an embodiment of the present disclosure.

Referring to FIG. 1, a ripple reduction loop circuit according to an embodiment of the present disclosure may be provided in a bandgap reference circuit. Hereinbelow, the ripple reduction loop circuit according to an embodiment of the present disclosure may also be referred to by terms such as a loop circuit, a ripple removal loop circuit, a Ripple Reduction Loop (RRL), a feedback circuit, and the like.

The ripple reduction loop circuit according to an embodiment of the present disclosure may include an oscillator 110, an offset detector 120, and a converter 130.

The oscillator 110 may be configured to oscillate based on a gate voltage of the bandgap reference circuit. To this end, the oscillator 110 may be connected to a gate of the bandgap reference circuit and may be implemented as a current-controlled oscillator (CCO). In this case, the oscillator 110 may represent the ripple occurring in the bandgap reference circuit as a frequency.

The offset detector 120 may be configured to detect an offset voltage—the difference between two voltages input to the amplifier—generated in the amplifier of the bandgap reference circuit by counting an oscillation frequency output from the oscillator 110. For example, the offset detector 120 may include: a counter 121 configured to count the oscillation frequency of the oscillator 110 based on a chopping frequency of the bandgap reference circuit; a sign detector 122 configured to detect a sign indicating a polarity of the offset voltage based on the chopping frequency and an output value of the counter 121; and an integrator 123 configured to output a control signal based on the sign detected by the sign detector 122.

The counter 121 may be implemented as an up/down counter and may output a counted value obtained by up-counting the oscillation frequency of the oscillator 110 from a rising edge and down-counting the oscillation frequency of the oscillator 110 from a falling edge for each chopping cycle of the chopping frequency.

The sign detector 122 may compare the counted value of the counter 121 with a reference value (e.g., 0) for each chopping cycle of the chopping frequency and output a bit value indicating the (+) or (−) sign of the offset voltage.

The integrator 123 may increase or decrease a control value using the bit value output from the sign detector 122 for each chopping cycle of the chopping frequency and may output a corresponding control signal. For example, when the current control value is “10” and the bit value output from the sign detector 122 indicates a (+) sign, the integrator 120 may output a control signal corresponding to the control value “9” by subtracting “1” from the current control value. To this end, an initial control value may be set in the integrator 123 based on the number of transistors provided in the converter 130. For example, if the converter 130 is provided with ‘20’transistors, the initial control value may be set to ‘10’.

The converter 130 may be provided in the amplifier of the bandgap reference circuit and may include a plurality of transistors. In an embodiment of the present disclosure, the converter 130 may be implemented as a DAC (Digital-to-Analog Converter) including a plurality of MOSFETs (Metal-Oxide-Semiconductor Field-Effect Transistors). In this case, the number of transistors that supply voltage to the amplifier in the bandgap reference circuit may be adjusted according to the control signal output from the offset detector 120, and accordingly, the offset between the two voltages input to the amplifier may be adjusted.

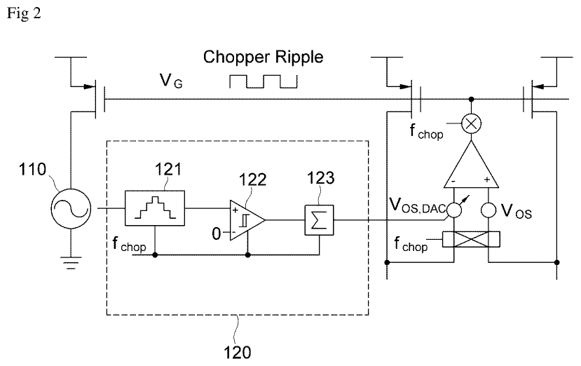

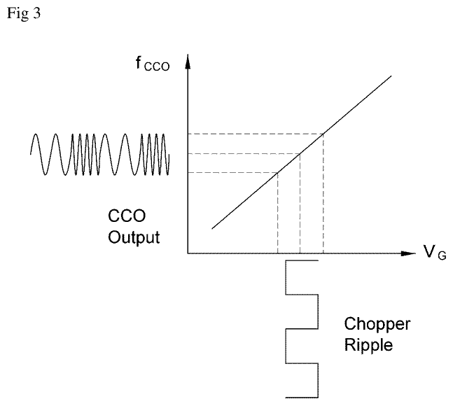

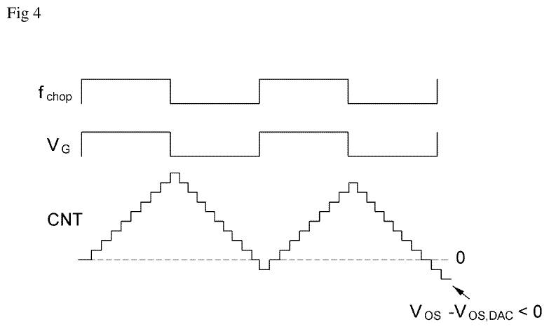

FIG. 2 is a view for explaining an offset detection process according to an embodiment of the present disclosure, FIG. 3 is a view illustrating an oscillation frequency used by a ripple reduction loop circuit according to an embodiment of the present disclosure, and FIG. 4 is a view illustrating an operation of a counter in a ripple reduction loop circuit according to an embodiment of the present disclosure.

Referring to FIGS. 2 to 4, the ripple reduction loop circuit according to an embodiment of the present disclosure may convert a ripple appearing at a node V_{G} into a frequency by using the oscillator 110. When the ripple (e.g., chopper ripple) appearing at the node V_{G} is passed through (e.g., applied to) the oscillator 110, the oscillator 110 may generate a high frequency when V_{G} is large and generate a low frequency when V_{G} is small, as illustrated in FIG. 3.

The oscillation frequency output from the oscillator 110 may be input to the counter 121 of the offset detector 120. The output of the counter 121 may indicate the (+) or (−) sign of the net offset voltage (net V_{OS}) of the amplifier in the bandgap reference circuit. Here, the net offset voltage (net V_{OS}) represents a difference between the two voltages input to the amplifier (V_{OS}-V_{OS,DAC} ).

The counter 121 may up-count the output of the oscillator 110 when the chopping frequency (f_{chop}) is ‘1’, as illustrated in FIG. 4, and down-count it when the chopping frequency is ‘0’. The counter 121 may output a positive number when, after one cycle of the chopping clock has elapsed, a phase of the current ripple and a phase of the chopping frequency are the same as each other, and may output a negative number when the phase of the current ripple and the phase of the chopping frequency are different from each other. Accordingly, ripple may be substantially eliminated by adjusting the input voltage V_{OS,DAC} of the amplifier by using the integrator 123 until the sign of the offset voltage becomes ‘0’. As described above, the ripple reduction circuit according to an embodiment of the present disclosure may determine the sign of the offset voltage through a single path, and thus has an advantage in that problems caused by mismatch between two paths, as occurs when using a notch filter, do not arise.

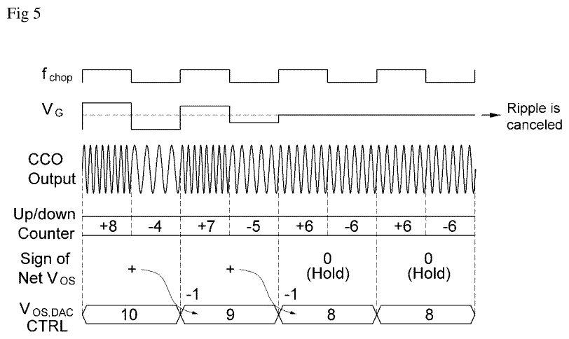

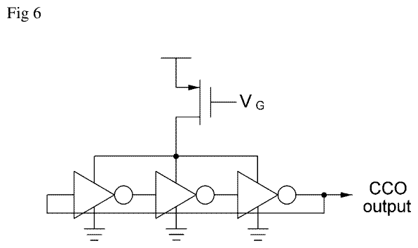

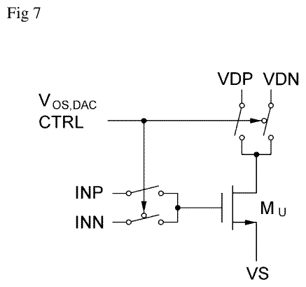

FIG. 5 is a view illustrating a process in which a ripple reduction loop circuit according to an embodiment of the present disclosure generates a control signal, FIG. 6 is an exemplary view illustrating an oscillator applied to a ripple reduction loop circuit according to an embodiment of the present disclosure, and FIG. 7 is an exemplary view illustrating a unit element within a converter of a ripple reduction loop circuit according to an embodiment of the present disclosure.

Referring to FIG. 5, the ripple reduction loop circuit according to an embodiment of the present disclosure may up-count the output of the oscillator (CCO output) from a rising edge and down-count the output of the oscillator from a falling edge for each chopping cycle of the chopping frequency (f_{chop}). As illustrated in FIG. 5, when eight pulses are output from the oscillator during a rising period and four pulses are output from the oscillator during a falling period in a first chopping cycle, the counter (up/down counter) may count the pulses and output a value of ‘4’. In this case, since the output value of the counter is positive, the ripple reduction loop circuit may determine the sign of the offset voltage (sign of net V_{OS}) as positive. When the sign of the offset voltage is positive, the ripple reduction loop circuit may reduce the offset voltage by outputting a control signal (V_{OS,DAC} CTRL) that causes the number of transistors supplying voltage to the amplifier to be reduced from ‘10’to ‘9’.

Subsequently, if seven pulses are output from the oscillator during a rising period and five pulses are output from the oscillator during a falling period in a second chopping cycle, the counter may output a value of ‘2’. In this case as well, since the output value of the counter is positive, the ripple reduction loop circuit may determine the sign of the offset voltage as positive and reduce the number of transistors supplying voltage to the amplifier to ‘8’. Additionally, when six pulses are output from the oscillator during a rising period and six pulses are output from the oscillator during a falling period in a third chopping cycle, the output value of the counter becomes “0,” and accordingly, the ripple reduction loop circuit determines that the offset between the voltages input to the amplifier has been eliminated and may maintain the current state, in which the number of transistors supplying voltage to the amplifier is ‘8’. Through this process, when the offset between the voltages input to the amplifier in the bandgap reference circuit is eliminated, the ripple of the gate voltage V_{G} may also be eliminated.

Meanwhile, a converter according to an embodiment of the present disclosure may be implemented entirely with MOSFETs without a capacitor, and if the oscillator is implemented as a 3-stage inverter-based current-controlled oscillator (CCO) as illustrated in FIG. 6, the converter may be implemented using a total of seven MOSFETs.

Each MOSFET in the converter may be implemented as illustrated in FIG. 7. In FIG. 7, V_{S} represents a source voltage of an input transistor of the amplifier, and INP and INN represent two inputs of the amplifier. VDP and VDN represent two drain voltages of the input transistor.

The gate and drain of each MOSFET M_{U} may be connected to INP and VDP, respectively, if the corresponding bit of the control signal (V_{OS,DAC} CTRL) is ‘1’, and may be connected to INN and VDN, respectively, if it is ‘0’. At this time, the source voltage does not need to be switched. By installing a MOSFET on the PMOS side in substantially the same way, an improved converter may be implemented.

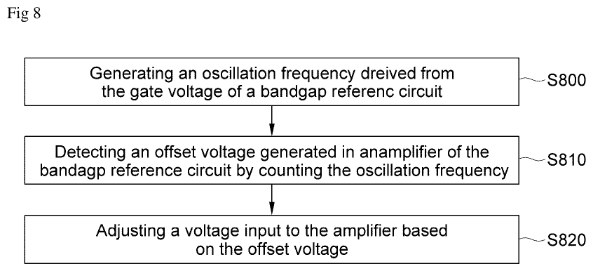

FIG. 8 is a flowchart illustrating a ripple reduction method according to an embodiment of the present disclosure.

Referring to FIG. 8, a ripple reduction loop circuit may generate an oscillation frequency based on a gate voltage of a bandgap reference circuit (S800). To this end, the ripple reduction loop circuit may include an oscillator, and the oscillator may be connected to a gate of the bandgap reference circuit.

The ripple reduction loop circuit may detect an offset voltage generated in an amplifier of the bandgap reference circuit by counting the oscillation frequency of the oscillator (S810). For example, the ripple reduction loop circuit may count the oscillation frequency of the oscillator based on a chopping frequency of the bandgap reference circuit and may detect a sign of the offset voltage by comparing the counted value with a reference value at each chopping cycle of the chopping frequency.

The ripple reduction loop circuit may adjust a voltage input to the amplifier of the bandgap reference circuit based on the offset voltage generated in the amplifier of the bandgap reference circuit (S820). For example, the ripple reduction loop circuit may increase or decrease a control value according to the sign of the offset voltage for each chopping cycle, generate a control signal corresponding to the control value, and output it to the converter. Each transistor within the converter may turn on/off the voltage supplied to the amplifier of the bandgap reference circuit according to the control value.

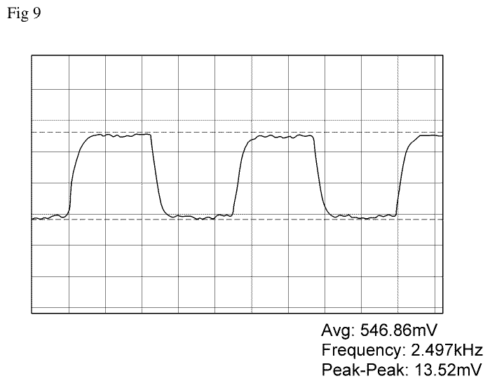

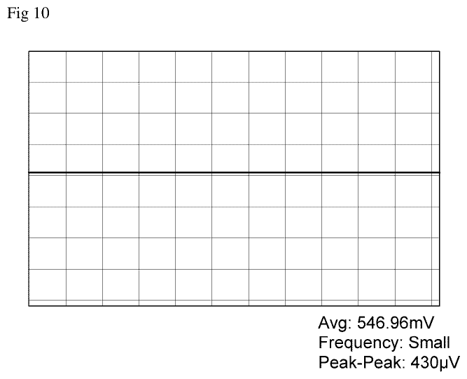

FIG. 9 is a view illustrating an output of a bandgap reference circuit with a ripple reduction loop turned off according to an embodiment of the present disclosure, and FIG. 10 is a diagram illustrating an output of a bandgap reference circuit with the ripple reduction loop turned on according to an embodiment of the present disclosure.

Referring to FIGS. 9 and 10, when the ripple reduction loop according to an embodiment of the present disclosure is turned off, an average voltage (reference voltage) of the bandgap reference circuit was about 546 mV and a ripple was about 13.5 mV. When the ripple reduction loop is turned on, the average voltage of the bandgap reference circuit was about 546 mV and the ripple was about 430 μV. Accordingly, it is confirmed that when using the ripple reduction loop according to an embodiment of the present disclosure, the ripple may be reduced by a factor of approximately 32 without a capacitor.

According to an embodiment of the present disclosure, since a ripple reduction loop may be implemented in a bandgap reference circuit without a capacitor, the effects of process scaling may be realized in more advanced processes, thereby achieving a significant cost reduction compared to conventional methods.

According to an embodiment of the present disclosure, substantially no offset is introduced by the ripple reduction loop, and degradation of resolution caused by ripple in a high-speed ADC circuit, as well as noise occurring at an output of a power regulator such as an LDO (Low DropOut), may be effectively mitigated at low cost.

The foregoing description is merely illustrative of the technical ideas of the present disclosure, and those of ordinary skill in the art to which the present disclosure pertains will be able to make various modifications and variations without departing from the essential characteristics of the present disclosure. Therefore, the embodiments disclosed in the present disclosure are not intended to limit the technical ideas of the present disclosure but rather to illustrate them, and the scope of the technical ideas of the present disclosure is not limited by these embodiments. The scope of protection of the present disclosure shall be interpreted based on the following claims, and all technical ideas falling within an equivalent scope shall be construed as being included within the scope of rights of the present disclosure.

What is claimed is:

1. A loop circuit for a bandgap reference circuit, comprising:
an oscillator configured to oscillate based on a gate voltage of the bandgap reference circuit;
an offset detector configured to detect an offset voltage generated in an amplifier of the bandgap reference circuit by counting an oscillation frequency output from the oscillator; and
a converter configured to adjust an input voltage of the amplifier based on a control signal output from the offset detector.

2. The loop circuit of claim 1, wherein the converter is provided in the amplifier and comprises a plurality of transistors.

3. The loop circuit of claim 2, wherein
the plurality of transistors comprise at least one MOSFET (Metal-Oxide-Semiconductor Field-Effect-Transistor).

4. The loop circuit of claim 1, wherein
the offset detector comprises:
a counter configured to count the oscillation frequency based on a chopping frequency of the bandgap reference circuit;
a sign detector configured to detect a sign of the offset voltage based on the chopping frequency and an output value of the counter; and
an integrator configured to output the control signal based on the sign.

5. The loop circuit of claim 4, wherein
the counter is configured to, for each chopping cycle of the chopping frequency, up-count the oscillation frequency from a rising edge and down-count the oscillation frequency from a falling edge, and output a resulting counted value.

6. The loop circuit of claim 5, wherein
the sign detector is configured to compare the counted value with a reference value for each chopping cycle and output a bit value indicating the sign of the offset voltage.

7. The loop circuit of claim 6, wherein
the integrator is configured to increase or decrease a control value using the bit value for each chopping cycle and output the control signal corresponding to the control value.

8. A method of reducing ripple in a bandgap reference circuit, the method comprising:
generating an oscillation frequency based on a gate voltage of the bandgap reference circuit;
detecting an offset voltage generated in an amplifier of the bandgap reference circuit by counting the oscillation frequency; and
adjusting a voltage input to the amplifier based on the offset voltage.

9. The method of claim 8, wherein
the detecting comprises:
counting the oscillation frequency based on a chopping frequency of the bandgap reference circuit; and
detecting a sign of the offset voltage based on the chopping frequency and the counted value.

10. The method of claim 9, wherein
the counting comprises, for each chopping cycle of the chopping frequency, up-counting the oscillation frequency from a rising edge and down-counting the oscillation frequency from a falling edge.

11. The method of claim 9, wherein
the detecting the sign of the offset voltage comprises:
detecting the sign by comparing the counted value with a reference value at each chopping cycle of the chopping frequency, and generating a bit value representing the sign.

12. The method of claim 11, wherein
the adjusting comprises:
increasing or decreasing a control value using the bit value for each chopping cycle and generating a control signal corresponding to the control value.
